(19) United States
(12) Patent Application Publication
(10) Pub. No.: US 2016/0056060 A1
(43) Pub. Date: Feb. 25, 2016

(54) CLEANING MEMBER, CLEANING APPARATUS, AND CLEANING METHOD

(71) Applicant: KABUSHIKI KAISHA TOSHIBA, Minato-ku (JP)

(72) Inventor: Shunsuke DOI, Yokkaichi (JP)

(73) Assignee: KABUSHIKI KAISHA TOSHIBA, Minato-ku (JP)

(21) Appl. No.: 14/625,891

(22) Filed: Feb. 19, 2015

(30) Foreign Application Priority Data
Aug. 20, 2014 (JP) 2014-167563

(51) Int. Cl. H01L 21/67; H01L 21/02

(52) U.S. Cl. CPC H01L 21/67046; H01L 21/67092; H01L 21/02096

(57) ABSTRACT

A cleaning member configured to clean a semiconductor substrate by relatively sliding over a surface of the semiconductor substrate is disclosed. The cleaning member includes a holding portion; and a brush portion supported by the holding portion and including an ion exchange resin.

### CROSS-REFERENCE TO RELATED APPLICATION(S)

This application is based upon and claims the benefit of priority from Japanese Patent Application No. 2014-167563, filed on, Aug. 20, 2014 the entire contents of which are incorporated herein by reference.

### FIELD

Embodiments disclosed herein generally relate to a cleaning member, a cleaning apparatus, and a cleaning method.

### BACKGROUND

In semiconductor device manufacturing, a cleaning process is typically performed after a semiconductor substrate, which may also be referred to as a wafer, is subjected to CMP (Chemical Mechanical Processing). The cleaning process removes foreign materials such as abrasive grains remaining on the surface of the semiconductor substrate after the polishing. Generally, the cleaning process is performed by placing a roll brush in contact with the surface of the semiconductor substrate and rotating the semiconductor substrate as well as the roll brush while supplying a cleaning liquid. The roll brush is typically shaped like a circular cylinder having protrusions on its outer peripheral surface. The outer peripheral portion of the roll brush is typically formed of synthetic resin such as PVA having a sponge-like structure. Thus, relative sliding of the semiconductor substrate and the roll brush physically removes foreign materials such as residual particles on the semiconductor substrate.

In the cleaning process of a semiconductor substrate, the so-called recontamination or reverse contamination is a concern in which particles once removed or collected by the roll brush is reattached to the surface of semiconductor substrate. Thus, improvement of cleaning performance is desired to resolve such problems.

### BRIEF DESCRIPTION OF THE DRAWINGS

FIG. 1 pertains to a first embodiment and is one example of a perspective view schematically illustrating the structure of a cleaning apparatus.

FIG. 2 pertains to the first embodiment and is one example of a front view illustrating the relative positioning of a semiconductor substrate, a roll brush, and a nozzle.

FIG. 3 pertains to the first embodiment and is one example of a vertical cross-sectional view schematically illustrating the structure of the roll brush.

FIG. 4 is one example of a chart describing the zeta potentials of different types of abrasive grains.

FIG. 5 pertains to a second embodiment and is one example of a vertical cross-sectional view schematically illustrating the structure of a roll brush.

FIG. 6 pertains to a third embodiment and is one example of a front view schematically illustrating the structure of a cleaning apparatus.

### DESCRIPTION

In one embodiment, a cleaning member is configured to clean a semiconductor substrate by relatively sliding over a surface of the semiconductor substrate. The cleaning member includes a holding portion; and a brush portion supported by the holding portion and including an ion exchange resin.

In one embodiment, a cleaning apparatus is configured to clean a surface of a semiconductor substrate. The cleaning apparatus includes a cleaning member provided with a holding portion and a brush portion supported by the holding portion and including an ion exchange resin; and a drive mechanism configured to slide the brush portion of the cleaning member relative to the surface of the semiconductor substrate.

In one embodiment, a method of cleaning a surface of a semiconductor substrate includes cleaning the surface of the semiconductor substrate by relatively sliding a brush portion over the surface of the semiconductor substrate. The brush portion includes an ion exchange resin and is supported by a holding portion. The brush portion and the holding portion are components of a cleaning member.

### EMBODIMENTS

Embodiments are described herein with reference to the accompanying drawings. The drawings are schematic and are not necessarily consistent with the actual structure or dimensions.

### First Embodiment

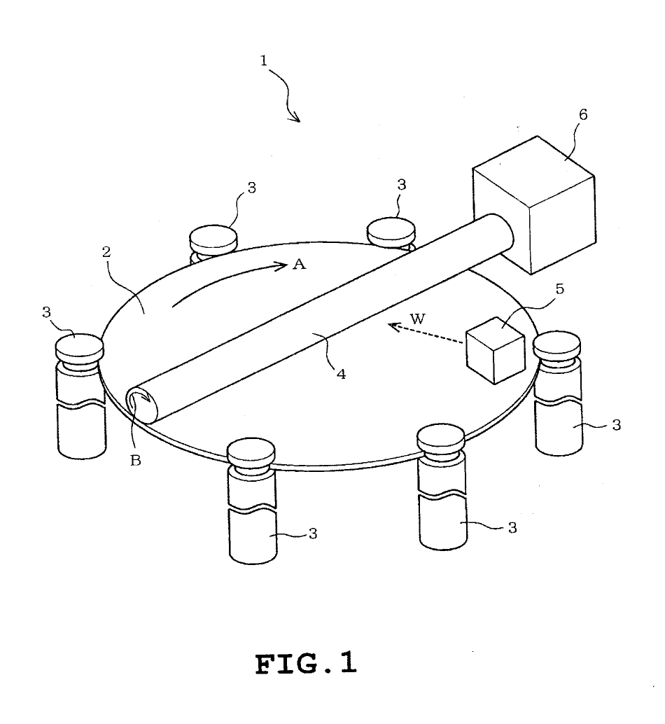

With reference to FIG. 1 to FIG. 4, a description will be given on a cleaning apparatus. Embodiments are described through, but not limited to, a cleaning apparatus application which is configured to execute a cleaning process for a semiconductor substrate or a wafer which has been subjected to a CMP (Chemical Mechanical Polishing) process.

FIG. 1 schematically illustrates the structure of cleaning apparatus 1 of the first embodiment. Cleaning apparatus 1 is provided with rotation support portion 3. Rotation support portion 3 is configured to support and rotate semiconductor substrate 2. Cleaning apparatus 1 is also provided with roll brush 4 serving as a cleaning member of the first embodiment. Roll brush 4 is rotated while being placed in contact with the surface, in this example, the upper surface of semiconductor substrate 2. Further, cleaning apparatus 1 is provided with cleaning liquid supplier 5 which is configured to supply a cleaning liquid to the surface of semiconductor substrate 2. Semiconductor substrate 2 comprises a semiconductor wafer for example. Semiconductor substrate 2 is shaped like a thin circular disc having a notch extending in a straight line on one outer peripheral portion thereof.

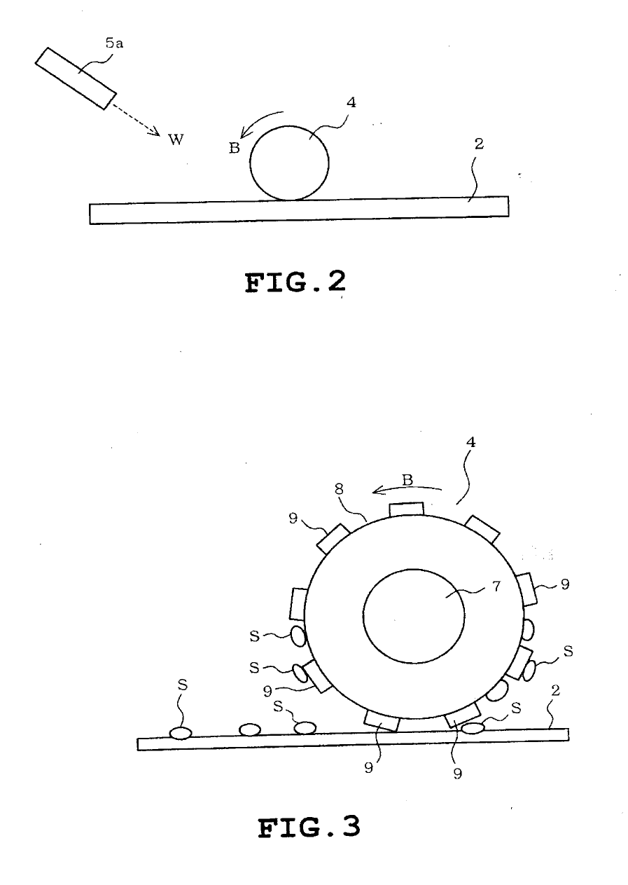

Rotation support portion 3 supports semiconductor substrate 2 so as to be level by providing support at the outer peripheral edge portion of semiconductor substrate 2 at for example, six locations. In addition to supporting semiconductor substrate 2, rotation support portion 3 is configured to rotate semiconductor substrate 2 in the direction of arrow A indicated in FIG. 1 about a vertical axis running through the central portion of semiconductor substrate 2. Roll brush 4 is generally shaped like a circular cylinder as illustrated in part in FIG. 2. Roll brush 4 is disposed on the upper surface of semiconductor substrate 2 being supported by rotation support portion 3 so as to extend horizontally along the diametric direction of semiconductor substrate 2.

One end of roll brush 4 is supported by support element 6. A drive mechanism not shown is disposed inside support element 6. The drive mechanism is configured to rotate roll brush 4 in the direction indicated by arrow B. Roll brush 4 will be later described in detail. Cleaning liquid supplier 5 is provided with nozzle 5a as illustrated in FIG. 2. Cleaning liquid supplier 5 is configured to supply cleaning liquid W to the upper surface of semiconductor substrate 2, being subjected to cleaning by roll brush 4, from nozzle 5a. Cleaning liquid W may be pure water or an alkaline/acidic cleaning liquid.

After being subjected to the CMP (Chemical Mechanical Polishing) process, semiconductor substrate 2 is set to rotation support portion 3 of cleaning apparatus 1 to execute the cleaning process. In the CMP process, metal film for example disposed above the surface of semiconductor substrate 2 is polished by a polish apparatus not shown. The surface, typically, the upper surface of semiconductor substrate 2 is polished by a polish pad in the CMP process while supplying slurry containing polish agent illustrated as abrasive grains S in FIG. 3. Examples of abrasive grains S include ceria (CeO₂), alumina (Al₂O₃), silica (SiO₂), or the like. Foreign objects such as abrasive grains S illustrated in FIG. 3 remain on the surface of semiconductor substrate 2 after the CMP process. Abrasive grains S are removed in the cleaning process.

Next, a description will be given on roll brush 4 serving as the cleaning member of the first embodiment with reference to FIG. 2 and FIG. 3. As illustrated in FIG. 3, roll brush 4 includes core 7 and brush portion 8. Core 7 serves as a holding portion and is generally shaped as a circular cylinder so as to appear as a round bar. Brush portion 8 is provided on the outer periphery of core 7. Core 7, being supported by support element 6, is configured to rotate. Brush portion 8 is detachably attached to core 7 so as be replaceable.

Brush portion 8 includes a main portion and multiplicity of protrusions 9. The main portion is shaped like a circular cylinder and is fitted over the outer periphery of core 7. Protrusions are provided on the outer peripheral surface of the main portion. In the first embodiment, the main portion of brush portion 8 comprises an ion exchange resin and more specifically a strongly basic anion exchange resin having a network structure. The main portion is porous and configured like a sponge provided with multiplicity of fine pores having a diameter ranging from several hundred nm to 1 μm. For example, the strongly basic anion exchange resin may be formed of basic ion exchange group bonded to a matrix of styrene-divinylbenzene system copolymer. The strongly basic anion exchange resin, when disassociated, possesses strong basicity and exchanges anions. The strongly basic anion exchange resin possesses strong positive zeta potential across the entire pH scale. The strongly basic anion exchange resin was used in this example, however, a weakly basic anion exchange resin may be used instead. The matrix of the ion exchange resin may comprise a copolymer of divinylbenzene and acrylic acid/methacrylic acid.

In the first embodiment, protrusion 9 comprises a PVA (polyvinyl alcohol) resin for example being porous like a sponge. PVA possesses negative zeta potential in a range of acidic to alkaline solution. The multiplicity of protrusions 9 are rendered structurally integral with or fixed to the main portion of brush portion 8 by two-color molding or by being bonded with adhesives.

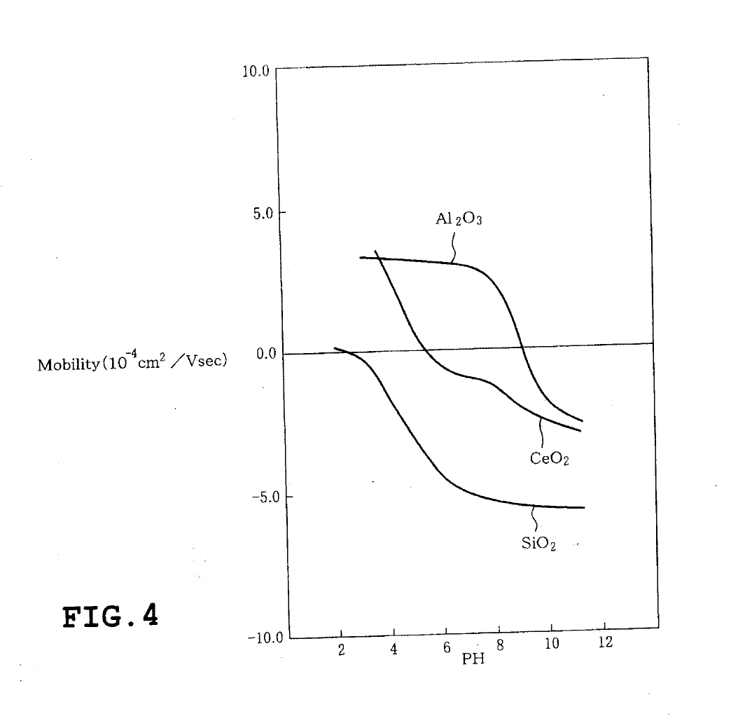

Next, a description will be given on a method of cleaning of the first embodiment through a cleaning process flow of semiconductor substrate 2 with reference to FIG. 4. In this example, description is given hereinafter with an assumption that: ceria is used as the polishing abrasive grain S serving as the polish agent in the CMP process; and pure water is used as cleaning liquid W in the cleaning process.

As described above, after being subjected to the CMP process, semiconductor substrate 2 is introduced into cleaning apparatus 1 and set to rotation support portion 3 so as to be laid out horizontally with the surface to be cleaned facing upward. At this instance, slurry used in the CMP process containing ceria abrasive grains S remain on the surface of semiconductor substrate 2. The cleaning process is started after moving roll brush 4 in a position to contact the upper surface of semiconductor substrate 2 set to rotation support portion 3.

In the cleaning process, cleaning liquid W, which is pure water in this example, is supplied to the upper surface of semiconductor substrate 2 from nozzle 5a of cleaning liquid supplier 5. Meanwhile, semiconductor substrate 2 is rotated in the direction of arrow A about a vertical axis while roll brush 4 is rotated in contact with the upper surface of semiconductor substrate 2 in the direction of arrow B. As a result, brush portion 8 of roll brush 4 relatively slides with the surface of semiconductor substrate 2 as illustrated in FIG. 3. As a result, foreign objects such as ceria grains S remaining on semiconductor substrate 2 are removed from the surface of semiconductor substrate 2 and washed away outside cleaning apparatus 1 with cleaning liquid W. More specifically, ceria grains S are removed so as to be mechanically scraped off of semiconductor substrate 2 by the operation of protrusions 9 provided at the outer periphery of roll brush 4. Ceria grains S separated from the surface of semiconductor substrate 2 are captured by permeating into the fine pores of brush portion 8 of roll brush 4 with cleaning liquid W. Cleaning liquid W is easily discharged from the pores.

FIG. 4 is a chart indicating zeta potentials of typical examples of abrasive grains used in polishing semiconductor substrate 2; namely, ceria (CeO₂), alumina (Al₂O₃), and silica (SiO₂). For example, ceria grains S exhibit negative zeta potential in pure water (pH 8). On the other hand, PVA (polyvinyl alcohol) used as the material of brush portion 8 exhibits a negative zeta potential in acidic to alkaline solutions. Thus, when brush portion 8 is entirely formed of PVA, brush portion 8 and ceria grains S become electrically repulsive with one another which prevents ceria grains S from being captured by brush portion 8. This may cause reattachment of ceria grains S to semiconductor substrate 2.

Roll brush 4 of the first embodiment is provided with brush portion 8 in which the main portion is formed of strongly basic anion exchange resin having positive zeta potential and protrusions 9 formed of PVA resin. Thus, protrusions 9 are capable of removing ceria grains S from the semiconductor substrate 2 by electric repulsion and mechanical operation. The main portion of brush portion 8 exclusive of protrusions 9 is capable of electrically adsorbing ceria grains S attached to its surface and ceria grains S permeating therein along with pure water W by the positive zeta potential possessed by strongly basic anion exchange resin. Brushing portion 8 comprising strongly basic anion exchange resin is capable of adsorbing large amount of ceria grains S therein since it has multiplicity of pores.

In the first embodiment, roll brush 4 is provided with brush portion 8 having a main portion comprising a strongly basic anion exchange resin and protrusions 9 comprising PVA resin. Thus, ceria grains S remaining on semiconductor substrate 2 can be effectively removed by mechanical removal and by electric adsorption while preventing reattachment to semiconductor substrate 2. As a result, it is possible to significantly improve the performance in cleaning the surface of semiconductor substrate 2.

Brush portion 8 comprising a strongly basic anion exchange resin may comprise a weakly basic anion exchange resin instead to obtain similar advantages. The first embodiment is described through an example in which brush portion 8 comprises strongly basic anion exchange resin or a weakly basic anion exchange resin with an assumption that cleaning is performed to remove abrasive grains S comprising ceria grains possessing negative zeta potential in cleaning liquid W. In contrast, when the abrasive grains in the cleaning liquid possesses positive zeta potential, strongly acidic cation exchange resin or a weakly acidic cation exchange resin may be used in instead. Strongly acidic cation exchange resin exhibits negative zeta potential across the entire pH scale. Thus, the application of the embodiments are not limited by the type of cleaning liquid W being used.

For example, when the film being polished on the surface of semiconductor substrate 2 is copper, silica is primarily used as polish grains. When an alkaline cleaning liquid is used in such case, the silica abrasive grains exhibit a negative zeta potential in the alkaline region of PH scale as indicated in FIG. 9. Thus, outstanding cleaning performance can be obtained by using roll brush 4 containing strongly basic anion exchange resin or a weakly basic anion exchange resin substantially equivalent to those used in the first embodiment.

For example, when the film being polished on the surface of semiconductor substrate 2 is tungsten, alumina is primarily used as polish grains. When an acidic cleaning liquid is used in such case, the alumina abrasive grains exhibit a positive zeta potential in the acidic region of PH scale as indicated in FIG. 4. Thus, it is possible to configure the main portion of brush portion 8 of roll brush 4 by strongly acidic cation exchange resin or weakly acidic cation exchange resin. It is thus, possible to improve the cleaning performance. In this example, protrusion 9 may be formed of PVA or other materials.

### Second Embodiment

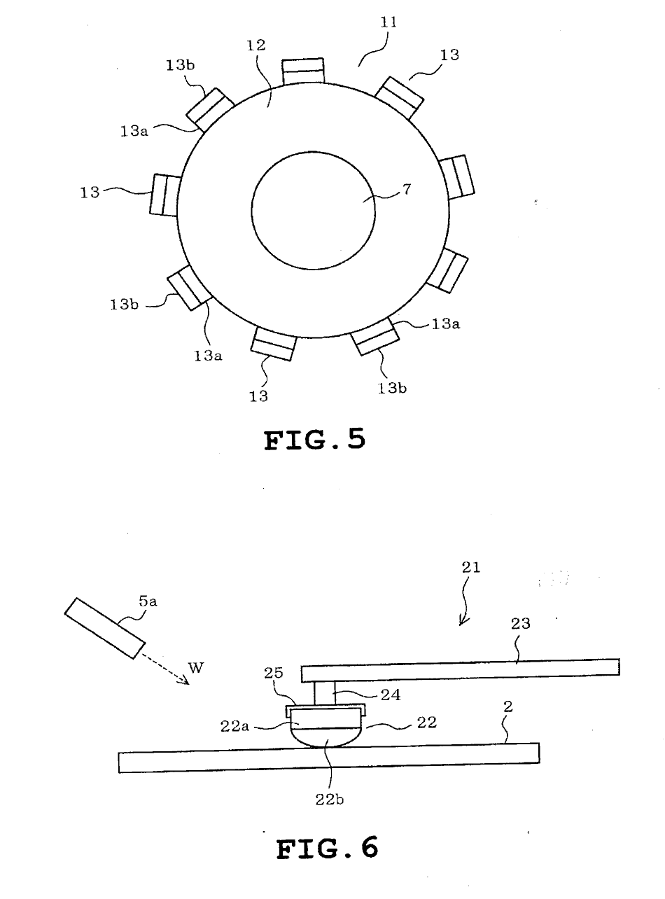

Next, a description will be given on a second embodiment with reference to FIG. 5. The second embodiment differs from the first embodiment in the structure of roll brush 11 serving as the cleaning member. Roll brush 11 includes core 7 and brush portion 12. Core is generally shaped as a circular cylinder so as to appear as a round bar. Brush portion 12 is provided on the outer periphery of core 7. Brush portion 12 is detachably attached to core 7 so as be replaceable. Brush portion 12 includes a main portion and multiplicity of protrusions 13. The main portion is shaped like a circular cylinder and is fitted over the outer periphery of core 7. Protrusions 13 are provided on the outer peripheral surface of the main portion so as to be structurally integral with the main portion.

In the second embodiment, the main portion of brush portion 12 comprises an ion exchange resin and more specifically a strongly basic anion exchange resin or a weakly basic anion exchange resin configured like a sponge provided with multiplicity of fine pores. Protrusion 13 is made of a double layer formed of different materials. The base end side of the double layer is also referred to as base end portion 13a and the tip side of the double layer is also referred to as tip portion 13b.

Tip portion 13b of protrusion 13 formed of for example a PVA (polyvinyl alcohol) resin for example being porous like a sponge. Base end portion 13a is structurally integral with the main portion of brush portion 12 and formed of for example strongly basic anion exchange resin and weakly basic anion exchange resin being porous like a sponge. Base end portion 13a of protrusion 13 is integrally molded with the main portion of brush portion 12, whereas tip portion 13b of protrusion 13 is rendered structurally integral with or fixed to base end portion 13a (brush portion 12) by two-color molding or by being bonded with adhesives.

Roll brush 11 structured as described above is used in the cleaning process of semiconductor substrate 2 which follows the CMP process carried out using ceria for example as polish abrasive grains S. Pure water is used for example as cleaning liquid W in the cleaning process. As was the case in the first embodiment, ceria grains S exhibit negative zeta potential in pure water serving as cleaning liquid W. Tip portion 13b of protrusion 13 provided in brush portion 12 of roll brush 11 is formed of PVA and thus, exhibit negative zeta potential. The main portion of brush portion 12 and base end portion 13a of protrusion 13 comprise strongly basic anion exchange resin or weakly basic anion exchange resin and thus, exhibit positive zeta potential.

Thus, tip portions 13b of protrusions 13 are capable of removing ceria grains S from the semiconductor substrate 2 by electric repulsion and mechanical operation during the cleaning operation in which roll brush 11 is rotated. The portion of brush portion 12 exclusive of tip portions 13b of protrusions 13, occupying most of brush portion 12, is capable of electrically adsorbing ceria grains S attached to its surface and ceria grains S permeating therein along with pure water W by the positive zeta potential possessed by strongly basic anion exchange resin or weakly basic anion exchange resin.

Thus, roll brush 11 of the second embodiment is capable of preventing the reattachment of ceria grains S remaining on semiconductor substrate 2 even more effectively and thereby significantly improves the performance in cleaning the surface of semiconductor substrate 2.

### Third Embodiment

FIG. 6 schematically illustrates the structure of cleaning apparatus 21 of the third embodiment. Cleaning apparatus 21 being configured as the so-called pencil cleaning apparatus is provided with pencil brush 22 serving as the cleaning member instead of roll brush 4 and 11 provided in the first embodiment and the second embodiment, respectively.

Cleaning apparatus 21 is provided with a rotation support portion, pencil brush 22, and a cleaning liquid supplier. The rotation support portion not illustrated is configured to support semiconductor substrate 2 in a horizontal state and rotate the same. The cleaning liquid supplier supplies cleaning liquid to the upper surface of semiconductor substrate 2 through nozzle 5a. Movable arm 23 extending in the horizontal direction is provided above the rotation support portion. Rotary shaft 24 extends downward from the tip of movable arm 23. Brush holder 25 serving as a holding portion is attached to the lower end of rotary shaft 24. Pencil brush 22 is detachably attached to the under surface of side of brush holder 25 so as to be replaceable.

Pencil brush 22 is generally shaped like a circular disc and the under surface side of pencil brush 22 protrudes downward in a round profile. In the third embodiment, pencil brush 22 is made of a double layer formed of different materials. The base end side of the double layer is also referred to as base end portion 22a and the tip side of the double layer is also referred to as tip portion 22b. Tip portion 22b in the lower side comprises PVA for example being porous like a sponge. Base end portion 22a in the upper side comprises ion exchange resin also being porous like a sponge. In case the abrasive grains to be removed possesses a negative zeta potential, a strongly basic anion exchange resin or a weakly basic anion exchange resin may be used. In case the abrasive grains to be removed possesses a positive zeta potential, a strongly acidic cation exchange resin or a weakly acidic cation exchange resin may be used.

Though not illustrated in detail, the rotation support portion rotates semiconductor substrate 2 by way of a drive mechanism. Further, movable arm 23 is configured to be transferred or swung in the horizontal direction. Further, rotary shaft 24 and consequently pencil brush 22 are rotated about a vertical axis by a drive mechanism not illustrated.

In executing a cleaning process with cleaning apparatus 21, semiconductor substrate 2 is loaded after the CMP process for example and set to the rotation support portion with the surface to be cleaned facing upward. In the cleaning process, cleaning liquid W such as pure water is supplied to the upper surface of semiconductor substrate 2 from nozzle 5a of cleaning liquid supplier. Meanwhile, semiconductor substrate 2 is rotated about a vertical axis as pencil brush 22 is rotated about a vertical axis while contacting the upper surface of semiconductor substrate 2. Pencil brush 22 is further transferred in the horizontal direction by movable arm 23.

Abrasive grains remaining on semiconductor substrate 2 is mechanically removed as tip portion 22b of pencil brush 22 rotates or slides in contact with the upper surface of semiconductor substrate 2. Abrasive grains along with cleaning liquid W permeate into the surface as well as the interior of base portion 22a of pencil brush 22 to be captured by electric adsorption. It is thus, possible to effectively inhibit reattachment of abrasive grains to semiconductor substrate 2 and thereby significantly improve the performance in cleaning the surface of semiconductor substrate 2.

### Other Embodiments

Though not described in detail in the foregoing embodiments, different types of roll brushes (brush portions) or pencil brushes formed of different types of ion exchange resins may be prepared for attachment to cleaning apparatus 21. Thus, the cleaning member may be replaced depending upon the type of semiconductor substrate to be cleaned, more specifically, the type of abrasive grains to be removed. Large amount of abrasive grains may accumulate in the brush portion of the roll brush or the pencil brush over repeated use. Continued use of the roll/pencil brush under such state may cause the so-called reverse contamination of semiconductor substrate 2. The cleaning member may be cleaned or replaced by a new one in such cases.

The foregoing embodiments were described through an example in which the cleaning process is performed after semiconductor substrate 2 is subjected to the CMP process. However, the cleaning members, cleaning apparatuses, and cleaning methods discussed in the embodiments may be applied to the cleaning performed in the process steps of the semiconductor manufacturing process flow. The cleaning member may be formed of various types of resins other than PVA discussed above. The abrasive grains may comprise materials different from those discussed above. Cleaning liquids different from those discussed above may be used in different embodiments. The structure of the cleaning apparatus may be modified for example so that both the top and under surfaces of the semiconductor substrate are cleaned simultaneously with two roll brushes.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A cleaning member configured to clean a semiconductor substrate by relatively sliding over a surface of the semiconductor substrate, the cleaning member comprising:
a holding portion; and
a brush portion supported by the holding portion and including an ion exchange resin.

2. The cleaning member according to claim 1, wherein the ion exchange resin comprises a strongly basic anion exchange resin or a strongly acidic cation exchange resin.

3. The cleaning member according to claim 1, wherein the ion exchange resin comprises a weakly basic anion exchange resin or a weakly acidic cation exchange resin.

4. The cleaning member according to claim 1, wherein the ion exchange resin comprises a matrix including a copolymer of styrene and divinylbenzene or a copolymer of acrylic acid/methacrylic acid and divinylbenzene.

5. The cleaning member according to claim 1, wherein the brush portion comprises a porous material.

6. The cleaning member according to claim 1 comprising a roll brush, wherein the brush portion is shaped like a circular cylinder, the brush portion being provided along an outer periphery of the holding portion.

7. The cleaning member according to claim 6, wherein the brush portion is provided with protrusions on an outer peripheral portion thereof.

8. The cleaning member according to claim 7, wherein the protrusions include a tip portion, and wherein at least the tip portion comprises a polyvinyl alcohol resin.

9. The cleaning member according to claim 1 comprising a pencil brush, wherein the brush portion is shaped like a circular disc.

10. The cleaning member according to claim 9, wherein the brush portion includes an upper layer and a lower layer, the lower layer having a tip portion comprising a polyvinyl alcohol resin.

11. The cleaning member according to claim 1, wherein the brush portion is configured to be attachable to, detachable from, and reattachable to the holding portion.

12. A cleaning apparatus configured to clean a surface of a semiconductor substrate comprising:
a cleaning member provided with a holding portion and a brush portion supported by the holding portion and including an ion exchange resin; and
a drive mechanism configured to slide the brush portion of the cleaning member relative to the surface of the semiconductor substrate.

13. The cleaning apparatus according to claim 12, further comprising a cleaning liquid supplier configured to supply a cleaning liquid to the surface of the semiconductor substrate.

14. The cleaning apparatus according to claim 12, wherein the cleaning member comprises a roll brush and the drive mechanism is provided with a mechanism configured to rotate the cleaning member.

15. The cleaning apparatus according to claim 12, wherein the cleaning member comprises a pencil brush and the drive mechanism is provided with a mechanism configured to transfer the cleaning member.

16. A method of cleaning a surface of a semiconductor substrate comprising:
cleaning the surface of the semiconductor substrate by relatively sliding a brush portion over the surface of the semiconductor substrate, the brush portion including an ion exchange resin and being supported by a holding portion, the brush portion and the holding portion being components of a cleaning member.

17. The method according to claim 16 being performed after the semiconductor substrate is polished by chemical mechanical polishing using a polishing agent.

18. The method according to claim 17, wherein the chemical mechanical polishing uses a slurry containing an abrasive grain of ceria as the polish agent, and
wherein the cleaning uses a cleaning liquid comprising pure water and the cleaning member includes a strongly basic anion exchange resin or a weakly basic anion exchange resin.

19. The method according to claim 17, wherein the chemical mechanical polishing uses a slurry containing an abrasive grain of alumina as the polish agent, and
wherein the cleaning uses an acidic cleaning liquid and the cleaning member includes a strongly acidic cation exchange resin or a weakly acidic cation exchange resin.

20. The method according to claim 17, wherein the chemical mechanical polishing uses a slurry containing an abrasive grain of silica as the polish agent, and
wherein the cleaning uses an alkaline cleaning liquid and the cleaning member includes a strongly basic anion exchange resin or a weakly basic anion exchange resin.
